(19) United States
(12) Patent Application Publication
(10) Pub. No.: US 2024/0372323 A1
(43) Pub. Date: Nov. 7, 2024

(54) Single-Mode External-Cavity Diode Laser Based on s-AFPF

(71) Applicant: Hubei University of Science and Technology, Xianning City (CN)

(72) Inventors: Xiao Xiao, Xianning City (CN); Jianquan Zhang, Xianning City (CN); Guopeng Zhou, Xianning City (CN); Zhibin Wang, Xianning City (CN)

(21) Appl. No.: 18/237,201

(22) Filed: Aug. 23, 2023

(30) Foreign Application Priority Data
May 5, 2023 (CN) 2023105077278

(51) Int. Cl. H01S 5/065; G02F 1/1335; H01S 5/00; H01S 5/026; H01S 5/14

(52) U.S. Cl. CPC H01S 5/0654; G02F 1/133548; H01S 5/0085; H01S 5/0262; H01S 5/141

(57) ABSTRACT

The disclosure provides a single-mode external-cavity diode laser based on an s-AFPF, relates to the technical field of tunable diode laser absorption spectroscopy. A piezoelectric ceramic actuator is used to change and modulate an output center wavelength of the laser, so that the center wavelength of laser light can periodically scan an absorption spectrum band of a gas to be detected. To better apply tunable diode laser absorption spectroscopy-wavelength modulation spectroscopy to the apparatus of the disclosure, a curved groove structure is further proposed, and this structure can limit a ping-pong effect of a steel ball when vibration of KHz level from the tunable diode laser absorption spectroscopy-wavelength modulation spectroscopy appears on the piezoelectric ceramic actuator. The tunable external-cavity diode laser based on a narrow-band interference filter designed by the disclosure accurately senses the types and concentrations of various gases.

### TECHNICAL FIELD

The disclosure relates to the technical field of tunable diode laser absorption spectroscopy, and in particular relates to a single-mode external-cavity diode laser based on an s-AFPF.

### BACKGROUND ART

Wavelength modulation spectroscopy (WMS) is a sensitive gas sensing method, belonging to tunable diode laser absorption spectroscopy (TDLAS). The tunable diode laser absorption spectroscopy uses an absorption principle of gas molecules and atoms to sense the temperature, concentration and other properties of a gas. The tunable diode laser absorption spectroscopy-wavelength modulation spectroscopy (TDLAS-WMS) changes and modulates a center wavelength of laser light with a narrow line width, so that the center wavelength of the laser light can periodically scan an absorption spectrum band of the gas to be detected. By using the tunable diode laser absorption spectroscopy-wavelength modulation spectroscopy (TDLAS-WMS), the disclosure can greatly improve detection sensitivity to 10⁻⁵-10⁻⁶ Hz^{1/2}, as 1/f noise is suppressed by shifting a detection frequency band to a higher frequency. Therefore, the TDLAS-WMS can accurately sense the type and concentration of the gas to be detected.

At present, the popular tunable diode laser used in a TDLAS-WMS system is a tunable monolithic diode laser, such as a DFB laser. However, the tunable external-cavity diode laser is not as popular as the tunable monolithic diode laser in the TDLAS-WMS system. An important reason for unpopularity is that the modulation speed of the tunable external-cavity diode laser is not fast enough. Therefore, to improve problems existing in the TDLAS-WMS, a single-mode external-cavity diode laser based on an s-AFPF is urgently needed to provide new technical application enlightenment for the TDLAS-WMS in modulation speed.

### SUMMARY OF THE DISCLOSURE

To solve technical problems in the prior art, the disclosure provides a single-mode external-cavity diode laser based on an s-AFPF, the laser being composed of a reflecting plane mirror, a wire grid polarizer, a first orthogonal bi-cylindrical lens, a Fabry-Perot laser diode, a second orthogonal bi-cylindrical lens, an s-AFPF, a first totally reflecting plane mirror, a second totally reflecting plane mirror and an actuator with a steel ball, which are disposed in sequence, wherein the steel ball is connected to the s-AFPF via a connecting rod, and used to control the s-AFPF to rotate anticlockwise around a rotating shaft disposed on the laser, the steel ball is in sliding connection with the actuator, and the actuator is a piezoelectric ceramic actuator;
two cleavage surfaces of the Fabry-Perot laser diode as a light source are plated with a first AR film for eliminating longitudinal modes;
the surfaces of both the first orthogonal bi-cylindrical lens and the second orthogonal bi-cylindrical lens are plated with a second AR film for eliminating longitudinal modes;
the actuator is used to move the second totally reflecting plane mirror forward and backward, and control the s-AFPF to rotate anticlockwise; and
the laser is used to generate a TE plane wave or TM plane wave with mode hop-free tuning performance by moving the second totally reflecting plane mirror forward and backward and controlling the s-AFPF to rotate anticlockwise.

Preferably, the first orthogonal bi-cylindrical lens and the second orthogonal bi-cylindrical lens are orthogonal cemented cylindrical doublets;
the first orthogonal bi-cylindrical lens and the second orthogonal bi-cylindrical lens are disposed on two sides of the Fabry-Perot laser diode respectively; and
the side, opposite to the first AR film, of each of the first orthogonal bi-cylindrical lens and second orthogonal bi-cylindrical lens is plated with the second AR film.

Preferably, the wire grid polarizer is a wire grid polarizing film with a diameter of 20 mm, used to generate TE polarized light or TM polarized light, wherein the wire grid polarizing film represents a thin metal wire/wire array tightly arranged on the top of a transparent substrate;
when the TE polarized light is generated, an intersection of the plane of the wire grid polarizing film and the horizontal plane should be perpendicular to an optical path, the plane of the wire grid polarizing film is not perpendicular to the optical path, and grid wires of the wire grid polarizing film are parallel to the horizontal plane; and
when the TM polarized light is generated, the plane of the wire grid polarizing film is perpendicular to the horizontal plane and not perpendicular to the optical path, and meanwhile, the grid wires are perpendicular to the horizontal plane.

Preferably, the s-AFPF is a circular single-cavity all-dielectric film Fabry-Perot filter with a diameter of 20 mm.

Preferably, a high refractive index dielectric of the s-AFPF is Ta₂O₅ film with a physical thickness of 191.247 nm.

Preferably, a low refractive index dielectric of the s-AFPF is SiO₂ film with a physical thickness of 272.073 nm.

Preferably, a substrate dielectric of the s-AFPF is BK7(K9) glass with a physical thickness of 2 mm.

Preferably, an included angle θ is provided between the connecting rod and the s-AFPF, and when the s-AFPF rotates anticlockwise, the included angle θ remains unchanged, wherein based on the included angle R, a rotation angle of the s-AFPF is acquired by acquiring a displacement x of the actuator from an initial position thereof and a distance N between the center of the rotating shaft and the center of the steel ball, which is used for a maximum transmission wavelength of the s-AFPF, and then a pass band center wavelength of the s-AFPF is controlled to occlude with a given external cavity longitudinal mode wavelength, to realize the mode hop-free tuning performance.

Preferably, a curved groove is further disposed at a sliding joint between the actuator and the steel ball, used to accommodate the steel ball, and prevent the steel ball from generating a ping-pong ball effect.

Preferably, the laser is applied to a TDLAS-WMS system for high-precision gas sensing.

The disclosure provides the technical effects as follows:
the apparatus provided by the disclosure uses the piezoelectric ceramic actuator to change and modulate an output center wavelength of the apparatus, so that the center wavelength of laser light can periodically scan an absorption spectrum band of the gas to be detected; and
compared with the tunable monolithic diode laser, the disclosure can accurately sense the types and concentrations of various gases, and can therefore be used to replace the tunable monolithic diode laser for high-precision gas sensing.

### BRIEF DESCRIPTION OF THE DRAWINGS

To describe the technical solutions in the examples of the disclosure or the prior art more clearly, the accompanying drawings required for describing the examples are briefly introduced below. It is apparent that the accompanying drawings described in the following are merely some examples of the disclosure, and those of ordinary skill in the art may still derive other drawings from these accompanying drawings without creative efforts.

FIG. 1 is a top view (horizontal plane) of a schematic structural diagram of a tunable external-cavity diode laser according to the disclosure;

FIG. 2 is a schematic diagram of a principle influencing the change of a round-trip optical path length in an external cavity according to the disclosure;

FIG. 3 is a schematic diagram of the relationship between pass band center wavelengths of an s-AFPF and corresponding fractional longitudinal mode numbers thereof after a TE or TM plane wave appears, when h is 2 mm, N is 70 mm, β is 0 degree and M is 400 mm according to an example of the disclosure;

FIG. 4 is a schematic diagram of the relationship between pass band center wavelengths of an s-AFPF and corresponding fractional longitudinal mode numbers thereof after a TE or TM plane wave appears, when N is 70 mm, β is 0 degree, M is 400 mm and h is a different value according to an example of the disclosure;

FIG. 5 is a schematic diagram of the relationship between pass band center wavelengths of an s-AFPF and corresponding fractional longitudinal mode numbers thereof after a TE or TM plane wave appears, when h is 2 mm, β is 0 degree, M is 400 mm and N is a different value according to an example of the disclosure;

FIG. 6 is a schematic diagram of the relationship between pass band center wavelengths of an s-AFPF and corresponding fractional longitudinal mode numbers thereof after a TE or TM plane wave appears, when h is 2 mm, N is 70 mm, M is 400 mm and 0 is a different value according to an example of the disclosure;

FIG. 7 is a schematic diagram of the relationship between pass band central wavelengths of an s-AFPF and corresponding fractional longitudinal mode numbers thereof after a TE or TM plane wave appears, when h is 2 mm, N is 70 mm, β is 0 degree and M is a different value according to an example of the disclosure;

FIG. 8 is a schematic theoretical distribution diagram of the raised height x2 of a steel ball on the basis of the front flat side of the actuator, when h is 2 mm, n is 70 mm, β is 0 degree and m is 400 mm according to an example of the disclosure;

FIG. 9 is a theoretical distribution diagram of the raised height x2+r of the center of a steel ball relative to the front flat side of the actuator, when h is 2 mm, n is 70 mm, β is 0 degree, M is 400 mm and r is 3 mm according to an example of the disclosure; and

FIG. 10 is a schematic distribution diagram of a curved groove for accommodating a steel ball, when h is 2 mm, N is 70 mm, β is 0 degree, M is 400 mm, and r is 3 mm according to an example of the disclosure, where (a) represents a schematic distribution diagram of the curved groove for accommodating the steel ball when mode hop-free performance is produced for a TE plane wave, and (b) represents a schematic distribution diagram of the curved groove for accommodating the steel ball when mode hop-free performance is produced for a TM plane wave.

### DETAILED DESCRIPTION OF THE DISCLOSURE

To make the objectives, technical solutions and advantages of examples of the application clearer, the technical solutions in the examples of the application will be described clearly and completely with reference to the accompanying drawings in the examples of the application. It is apparent that the described examples are merely some of rather than all the examples of the application. Assemblies of the examples of the application, which are generally described and illustrated in the accompanying drawings herein, may be arranged and designed in various different configurations. Therefore, the following detailed description of the examples of the application provided in the accompanying drawings is not intended to limit the protection scope of the application, but merely represents selected examples of the application. Based on the examples of the application, all other examples obtained by those skilled in the art without creative efforts should fall within the protection scope of the application.

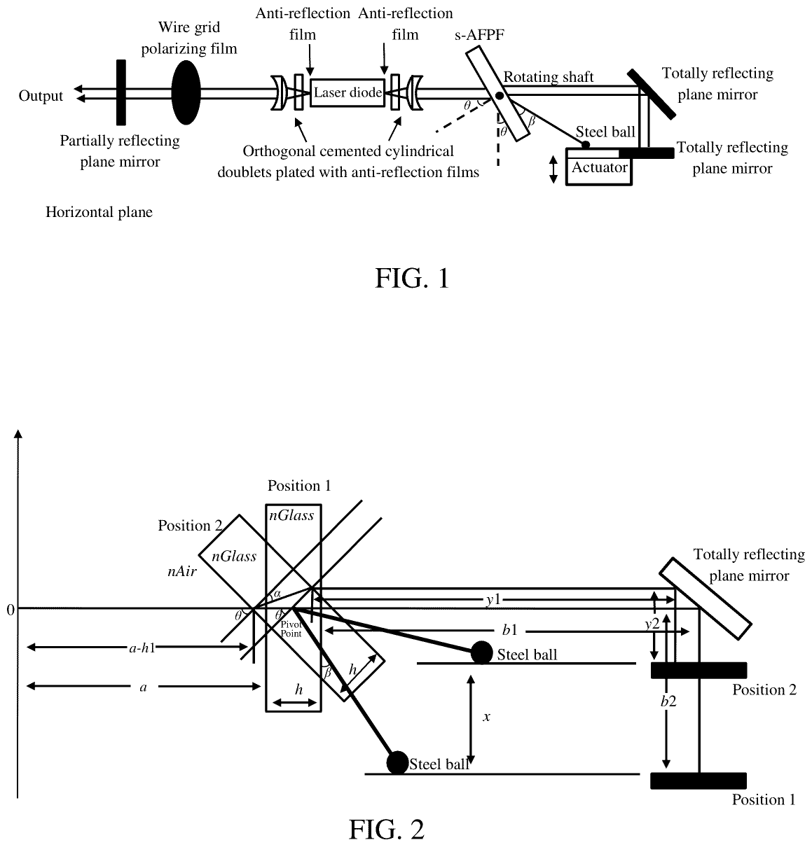

As shown in FIG. 1-FIG. 10, Example 1: the disclosure provides an improved tunable external-cavity diode laser based on a narrow-band interference filter, to serve as a light source of a tunable diode laser absorption spectroscopy-wavelength modulation spectroscopy system. The disclosed apparatus may use a piezoelectric ceramic actuator to change and modulate an output center wavelength thereof, so that the center wavelength of laser light can periodically scan an absorption spectrum band of a gas to be detected. To better apply tunable diode laser absorption spectroscopy-wavelength modulation spectroscopy to the apparatus of the disclosure, a curved groove structure is further proposed. This structure can limit a ping-pong ball effect of a steel ball when vibration of KHz level from the tunable diode laser absorption spectroscopy-wavelength modulation spectroscopy appears on the piezoelectric ceramic actuator. Compared with the tunable monolithic diode laser, the tunable external-cavity diode laser based on the narrow-band interference filter can accurately sense the types and concentrations of various gases. Therefore, the tunable external-cavity diode laser based on the narrow-band interference filter may be used to perform high-precision gas sensing in the tunable diode laser absorption spectroscopy-wavelength modulation spectroscopy system, replacing the tunable monolithic diode laser.

The disclosure is mainly designed for the application of the TDLAS-WMS in the external-cavity diode laser based on the narrow-band interference filter, where the narrow-band interference filter refers to a single-cavity all-dielectric film Fabry-Perot filter (s-AFPF), and the transmittance characteristics of the s-AFPF have been theoretically studied by using a transmission matrix method. Such tunable external-cavity diode laser may be applied to environmental gas monitoring, atomic and molecular laser spectrum research, accurate measurement and other fields.

The disclosure provides a single-mode external-cavity diode laser apparatus based on 1550 nm linear tunable continuous waves (CW) of a s-AFPF. As shown in FIG. 1, the tunable external-cavity diode laser uses a novel external cavity tuning mechanism, to realize synchronous change of a pass band center wavelength of a light splitting element, s-AFPF, of the laser and a fixed external cavity longitudinal mode wavelength. Through theoretical calculation, the front flat side, abutting against the steel ball, of the actuator may be replaced by a curved surface, thereby converting a mode hopping wavelength tuning region into a mode hop-free wavelength tuning region.

FIG. 1 shows an external cavity apparatus maintaining a TE or TM plane wave as a single output longitudinal mode, when the single-cavity all-dielectric film Fabry-Perot filter rotates. The functions of the single actuator are: 1) moving a totally reflecting plane mirror, which serves as one end of an external cavity, forward and backward; and 2) rotating the single-cavity all-dielectric film Fabry-Perot filter around a fixed rotating shaft. If the actuator moves forward, the external cavity is shortened, and the given longitudinal mode wavelength decreases in a quasi-linear manner. Meanwhile, the incident angle θ of a beam at the s-AFPF increases as the actuator pushes the steel ball forward. With the increase of 0, the pass band center wavelength of the s-AFPF decreases to a smaller value, which has a quasi-linear correlation with the cosine of 0.

Under appropriate design parameters, for the TE or TM plane wave, the given external cavity longitudinal mode wavelength can well occlude with the pass band center wavelength of the s-AFPF within a considerable range, thereby producing mode hop-free tuning performance.

In FIG. 1, the TE plane wave has an electric field vector perpendicular to the horizontal plane, and the TM plane wave has an electric field vector parallel to the horizontal plane. A circular single-cavity all-dielectric film Fabry-Perot filter Air|(HL)?H-2L-H(LH)?|Glass having a diameter of 20 mm is inserted into the external cavity of the tunable external-cavity diode laser. “H” represents a high refractive index dielectric, “L” represents a low refractive index dielectric, and the optical thickness of both is one quarter wavelength. In the s-AFPF, the high refractive index dielectric is Ta₂O₅ (film), the low refractive index dielectric is SiO₂ (film), and a substrate dielectric is BK7(K9) glass (N-BK7SCHOTT). The physical thicknesses of an “H” layer, a “L” layer and a “glass” substrate are 191.247 nm, 272.073 nm and 2 mm, respectively. The s-AFPF is perpendicular to the horizontal plane, but not perpendicular to an optical path, and can rotate about a rotating shaft thereof. A light source in the tunable external-cavity diode laser is a Fabry-Perot (FP) laser diode, of which two cleavage surfaces are plated with AR films, so the generated longitudinal mode is eliminated. To shape and collimate an elliptical beam emitted by an FP laser diode, two orthogonal bi-cylindrical lenses are placed on each side of the FP laser diode in the disclosure; and the AR film is plated on the surface of each orthogonal bi-cylindrical lens, so the generated longitudinal modes are also eliminated. To ensure that the tunable external-cavity diode laser outputs pure TE or TM polarized light, a circular wire grid polarizing film with a diameter of 20 mm is inserted into the external cavity of the tunable external-cavity diode laser in the disclosure, so that the TE wave passes and the TM wave is reflected away, or the TM wave passes and the TE wave is reflected away. The wire grid polarizing film is closely arranged fine metal wires/wire array located on the top of a transparent substrate. Generally, the light is reflected by the wire grid polarizing film when the electric field vector of the light is parallel to grid wires, and the light passes through the wire grid polarizing film when the electric field vector of the light is perpendicular to the grid wires. According to the principle of the wire grid polarizing film, if the disclosure only wants to maintain the output of the TE wave, an intersection of the plane of the wire grid polarizing film and the horizontal plane should be perpendicular to an optical path, the plane of the wire grid polarizing film should not be perpendicular to the optical path, and meanwhile, the grid wires should be parallel to the horizontal plane. If the disclosure only wants to maintain the output of the TM wave, the plane of the wire grid polarizing film should be perpendicular to the horizontal plane and not perpendicular to the optical path, and meanwhile, the grid wires should be perpendicular to the horizontal plane.

In FIG. 1, the tunable external-cavity diode laser apparatus uses the single actuator to control the length of the external cavity and the incident angle of the beam at the s-AFPF. The disclosure assumes that an initial position of the actuator is a position where the incident angle of the beam at the s-AFPF is zero. When the actuator moves forward from the initial position, the length of the external cavity decreases, and the single longitudinal mode wavelength is shortened in a quasi-linear manner. As the actuator pushes the steel ball forward step by step, the s-AFPF is also driven to rotate anticlockwise around the rotating shaft, so that the incident angle of the beam at the s-AFPF increases, and a light intensity peak transmittance wavelength of the s-AFPF is thus reduced in a quasi-linear manner. For the given s-AFPF, if the distance from the center of the rotating shaft to the center of the steel ball is set properly, the pass band center wavelength of the s-AFPF may well occlude with the given external cavity longitudinal mode wavelength, thereby realizing the mode hop-free tuning performance.

The disclosure sets the initial position of the actuator to be the position where the incident angle of the beam at the s-AFPF is zero. When the actuator moves forward step by step from the initial position, the incident angle at the s-AFPF and the optical path of the external cavity change simultaneously. In the disclosure, a displacement of the actuator from the initial position thereof is set to be x, the physical thickness of a substrate of the s-AFPF is set to be h, the refractive index of the substrate of the s-AFPF is set to be nGlass, the refractive index of the air is set to be nAir, and the distance between the center of the rotating shaft and the center of the steel ball is set to be N.

Meanwhile, for the TE plane wave, the pass band center wavelength of the s-AFPF is set to be wₛ(x) in the disclosure; for the TM plane wave, the pass band center wavelength of the s-AFPF is set to be wₚ(x) in the disclosure; the round-trip optical path length in the external cavity is set to be OPL(x) in the disclosure.

A frictional longitudinal mode number mₛ(x) is defined in the disclosure, which is the ratio of OPL(x) to wₛ(x),
and a frictional longitudinal mode number mₚ(x) is defined, which is the ratio of OPL(x) to wₚ(x).

$${m}_{s} ( x ) = \frac{OPL ( x )}{{w}_{s} ( x )} ( for the TE plane wave ) , \qquad ( 1 )$$

$${m}_{p} ( x ) = \frac{OPL ( x )}{{w}_{p} ( x )} ( for the TM plane wave ) , \qquad ( 2 )$$

The frictional longitudinal mode number ns(x) or mₚ(x) is just a real number, which represents the longitudinal mode number corresponding to the maximum transmission wavelength of the s-AFPF.

If OPL(x) closely occlude with wₛ(x) or wₚ(x) during the change of x, mₛ(x) or mₚ(x) remains almost unchanged, and ECDL with the output of wₛ(x) or wₚ(x) can realize mode hop-free tuning in a relatively wide range.

FIG. 2 shows detailed elements that affect the change of the round-trip optical path length in the external cavity when the actuator moves forward from the initial position thereof. In FIG. 2, the external cavity round-trip optical path difference between the initial position “Position1” and a current position “Position2” is set to be OPD in the disclosure.

$$OPD = 2 \{ ( a * nAir + h * nGlass + {b}_{1} * nAir + {b}_{2} * nAir ) - [ \text{} ( a - {h}_{1} ) * nAir + \frac{h * nGlass}{cos α} + {y}_{1} * nAir + {y}_{2} * nAir ] \} , \qquad ( 3 )$$

$$a + h + {b}_{1} + {b}_{2} - x = ( a - {h}_{1} ) + \frac{h * cos ( θ - α )}{cos α} + {y}_{1} + {y}_{2} , \qquad ( 4 )$$

By substituting Formula (4) into Formula (3) to eliminate y₁+y₂, the following can be obtained:

$$OPD = 2 * [ h * nGlass - \frac{h * nGlass}{cos α} - h * nAir + x * nAir + \frac{h * cos ( θ - α )}{cos α} * nAir ] , \qquad ( 5 )$$

$$\begin{matrix}cos α = \sqrt{1 - {( sin α )}^{2}} = \sqrt{1 - {( \frac{nAir * sin θ}{nGlass} )}^{2}} \\ = \sqrt{\frac{\begin{matrix}{nGlass}^{2} * {N}^{2} - {nAir}^{2} * [ {( N * cos β )}^{2} - cos 2 β * {( N * cos β - x )}^{2} - \\ sin 2 β * ( N * cos β - x ) * \sqrt{{N}^{2} - {( N * cos β - x )}^{2}} ]\end{matrix}}{{nGlass}^{2} * {N}^{2}}} \\ = \sqrt{\frac{\begin{matrix}{nGlass}^{2} * {N}^{2} - {nAir}^{2} * {( N * cos β )}^{2} + {nAir}^{2} * cos 2 β * {( N * cos β - x )}^{2} + \\ {nAir}^{2} * sin 2 β * ( N * cos β - x ) * \sqrt{{N}^{2} - {( N * cos β - x )}^{2}}\end{matrix}}{nGlass * N}}\end{matrix} , \qquad ( 6 )$$

$${( sin θ )}^{2} = \frac{\begin{matrix}{( N * cos β )}^{2} - cos 2 β * {( N * cos β - x )}^{2} - \\ sin 2 β * ( N * cos β - x ) * \sqrt{{N}^{2} - {( N * cos β - x )}^{2}}\end{matrix}}{{N}^{2}} , \qquad ( 7 )$$

$$cos α = \sqrt{\frac{\begin{matrix}{nGlass}^{2} * {N}^{2} - {nAir}^{2} * {( N * cos β )}^{2} + {nAir}^{2} * cos 2 β * {( N * cos β - x )}^{2} + \\ {nAir}^{2} * sin 2 β * ( N * cos β - x ) * \sqrt{{N}^{2} - {( N * cos β - x )}^{2}}\end{matrix}}{nGlass * N}} , \qquad ( 8 )$$

$$cos ( θ - α ) = cos θ * cos α + sin θ * sin α = \sqrt{1 - {( sin θ )}^{2}} * cos α + \sqrt{{( sin θ )}^{2}} * \sqrt{1 - {( cos α )}^{2}} , \qquad ( 9 )$$

A schematic diagram of the change ofthe round-trip optical path length in the external cavity whenthe actuator moves forward from the initial positionthereof. It should e noted that whenthe steel ball is also pushed forward, the s-AFPF rotates around the rotating shaft. The distance from the center ofthe rotating shaft to the center ofthe steel ball is N (not marked). A rotation angle θ is determinedby x, β and N according to Formula (7). For TE and TM plane waves, θ determines the maximum transmission wavelengths of the s-AFPF.

By substituting Formulas (8) and (9) into Formula (5), the difference between the round-trip optical paths in the external cavity OPD(x) can be obtained. When the displacement of the actuator from the initial position thereof is x, the fractional longitudinal mode number corresponding to the pass band center wavelength of the s-AFPF is:

$${m}_{s} ( x ) = \frac{OPL ( x )}{{w}_{s} ( x )} = \frac{OPL ( 0 ) - OPD ( x )}{{w}_{s} ( x )} ( for the TE plane wave ) , \qquad ( 10 )$$

$${m}_{p} ( x ) = \frac{OPL ( x )}{{w}_{p} ( x )} = \frac{OPL ( 0 ) - OPD ( x )}{{w}_{p} ( x )} ( for the TM plane wave ) , \qquad ( 11 )$$

where OPL(O) is an initial condition, which may be expressed as:

$$OPL ( 0 ) = 2 * ( nGlass * h + nAir * M ) , \qquad ( 12 )$$

M is the physical length of an air dielectric in a laser resonator when the actuator is in the initial position thereof.

For TE and TM plane waves, based on the formulas (10) and (11), the fractional longitudinal mode numbers, when the actuator moves from the initial position thereof to any position, corresponding to the pass band center wavelengths of the s-AFPF can be calculated in the disclosure.

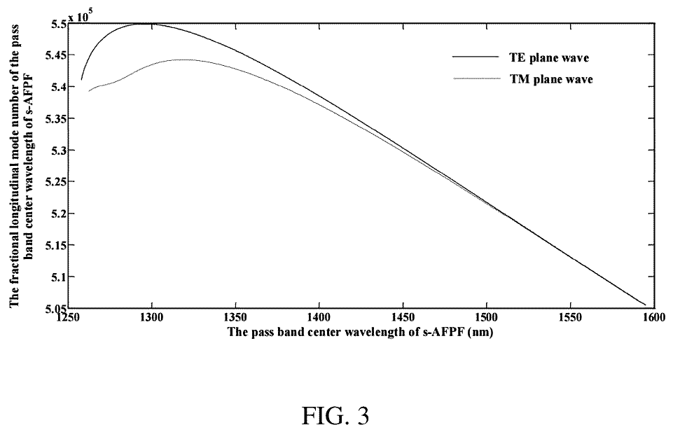

Example 2: to verify the reliability of the disclosure, the following test process is carried out in the disclosure: when h is 2 mm, N is 70 mm, β is 0 degree, and M is 400 mm, FIG. 3 shows the relationship between the pass band center wavelengths of the s-AFPF and the corresponding fractional longitudinal mode numbers after a TE or TM plane wave appears, and accordingly, the incident angle of the beam at the s-AFPF is changed from 0 degree to 85 degree.

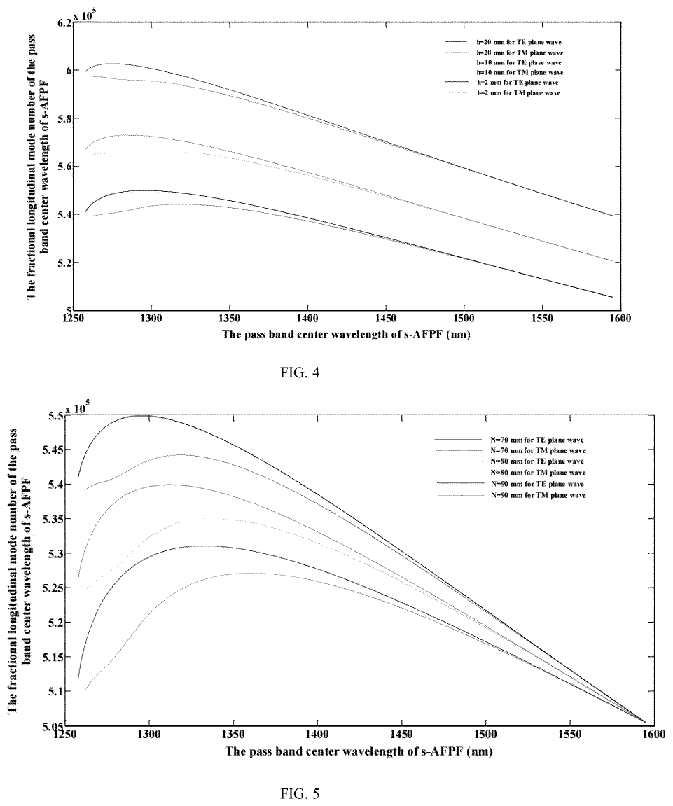

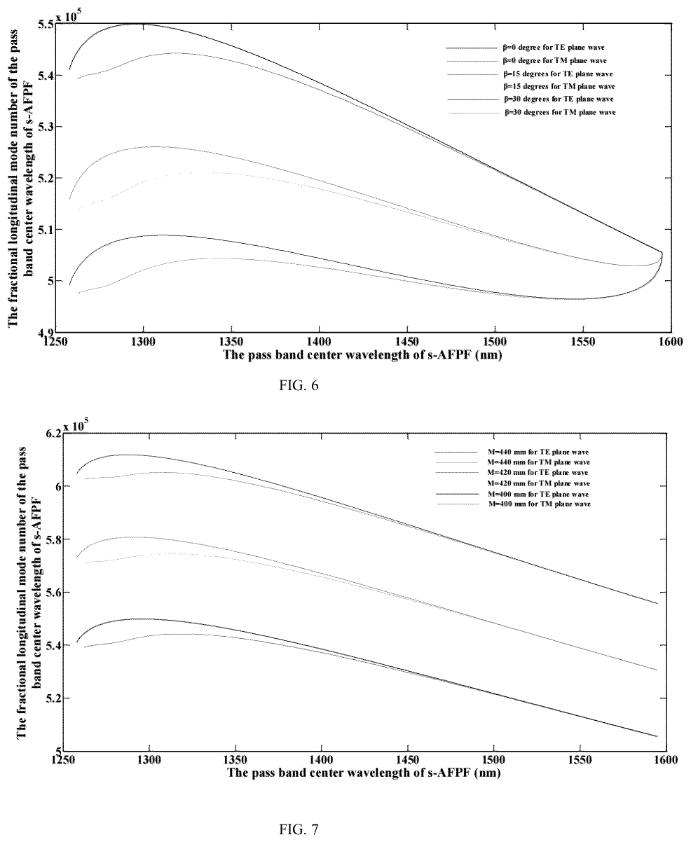

It can be seen from FIG. 3 that, for the TE and TM plane waves, as the actuator moves forward from the initial position thereof, the fractional longitudinal mode numbers corresponding to the pass band center wavelengths of the s-AFPF first increase and then decrease. Therefore, for the TE and TM plane wave, a range in which the pass band center wavelength of the s-AFPF and the external cavity longitudinal mode wavelength can be changed simultaneously is limited. The limited range corresponds to the top of a TE or TM curve in FIG. 3, where, as shown in FIG. 4, if only the value of h is changed, “mₛ(x)−wₛ(x)” and “mₚ(x)−wₚ(x)” curves can be changed; as shown in FIG. 5, if only the value of N is changed, “mₛ(x)−wₛ(x)” and “mₚ(x)−wₚ(x)” curves can be changed; as shown in FIG. 6, if only the value of 0 is changed, “mₛ(x)−wₛ(x)” and “mₚ(x)−wₚ(x)” curves can be changed; and as shown in FIG. 7, if only the value of M is changed, “mₛ(x)−wₛ(x)” and “mₚ(x)−wₚ(x)” curves can be changed.

The disclosure also gives the theoretical distribution of the raised height x2 of the steel ball in the apparatus on the basis of the front flat side of the actuator, which can produce mode hop-free performance for the TE or TM plane wave, as shown in FIG. 8. x2+r is the raised height of the center of the steel ball relative to the front flat side of the actuator, where r is the radius of the steel ball.

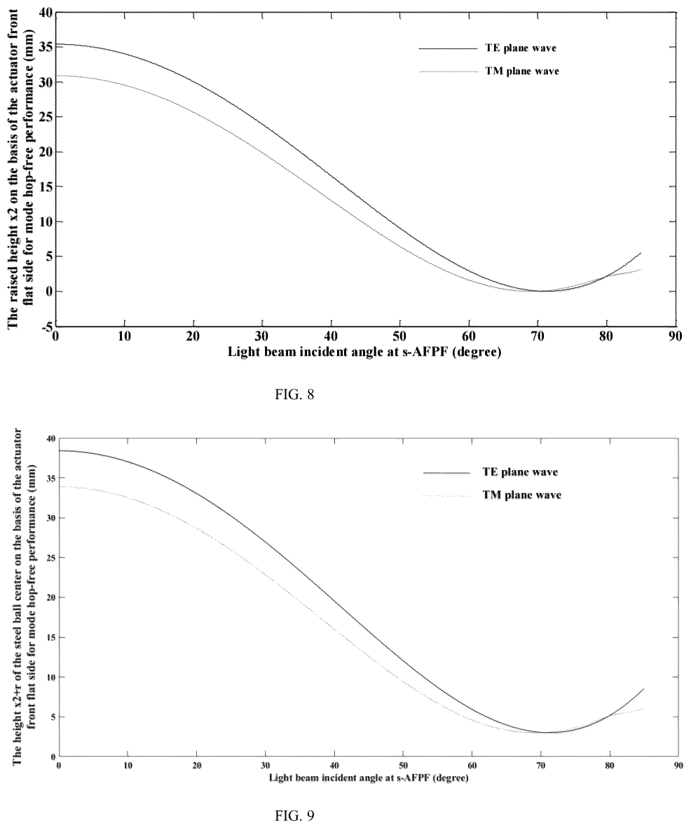

The theoretical distribution of the raised height x2+r of the center of the steel ball on the basis of the front flat side of the actuator is shown in FIG. 9, which can produce the mode hop-free performance for the TE or TM plane wave.

According to the disclosure, a center trajectory of the steel ball can be obtained, and a corresponding curved surface can be processed pertinently. Through the action of the curved surface on the s-AFPF, mode hop-free wavelength tuning having a quasi-linear relationship with the displacement of the actuator can be realized. Furthermore, the disclosure uses two different curved surfaces to realize mode hop-free wavelength tuning of the TE and TM plane waves respectively. However, if the TDLAS-WMS is applied to the current apparatus in FIG. 1, it is difficult for the curved surface to work as well as it should. This is because when vibration of KHz level in the TDLAS-WMS appears on the actuator, even if there is a force to push the steel ball back onto the curved surface, the steel ball also bounces forward like a ping-pong ball. To solve this problem, the disclosure processes a curved groove which can just accommodate the steel ball. In this way, when there is the vibration of KHz level on the actuator, the steel ball does not bounce forward like the ping-pong ball because it is limited in the curved groove.

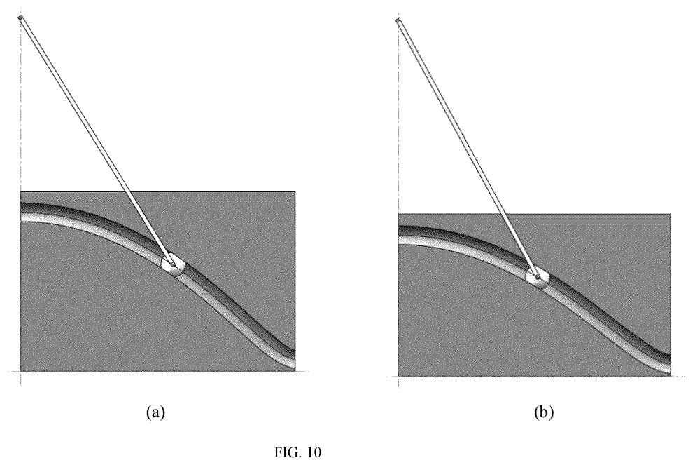

According to the center trajectory of the steel ball and the diameter of the steel ball, the disclosure processes the curved groove which can just accommodate the steel ball, as shown in FIG. 10. Through this design, the TDLAS-WMS can be applied to the tunable ECDL based on narrow-band interference filter, which can accurately sense the type and concentration of the gas to be detected. In addition, the tunable ECDL based on narrow-band interference filter has a very wide mode hop-free wavelength tuning range, and is thus able to sense various gases. In a word, compared with the tunable monolithic diode laser, the tunable ECDL based on narrow-band interference filter may be able to accurately sense the types and concentrations of various gases.

Although the preferred examples of the disclosure have been described, additional changes and modifications may be made to these examples once the basic inventive concepts are known to those skilled in the art. Therefore, the appended claims are intended to be interpreted as including the preferred example and all changes and modifications that fall within the scope of the disclosure.

1. A single-mode external-cavity diode laser based on an s-AFPF, the laser being composed of a reflecting plane mirror, a wire grid polarizer, a first orthogonal bi-cylindrical lens, a Fabry-Perot laser diode, a second orthogonal bi-cylindrical lens, an s-AFPF, a first totally reflecting plane mirror, a second totally reflecting plane mirror and an actuator with a steel ball, which are disposed in sequence, wherein the steel ball is connected to the s-AFPF via a connecting rod, and used to control the s-AFPF to rotate anticlockwise around a rotating shaft disposed on the laser, the steel ball is in sliding connection with the actuator, and the actuator is a piezoelectric ceramic actuator;
two cleavage surfaces of the Fabry-Perot laser diode as a light source are plated with a first AR film for eliminating longitudinal modes;
the surfaces of both the first orthogonal bi-cylindrical lens and the second orthogonal bi-cylindrical lens are plated with a second AR film for eliminating longitudinal modes;
the actuator is used to move the second totally reflecting plane mirror forward and backward, and control the s-AFPF to rotate anticlockwise; and
the laser is used to generate a TE plane wave or TM plane wave with mode hop-free tuning performance by moving the second totally reflecting plane mirror forward and backward and controlling the s-AFPF to rotate anticlockwise.

2. The single-mode external-cavity diode laser based on an s-AFPF according to claim 1, wherein
the first orthogonal bi-cylindrical lens and the second orthogonal bi-cylindrical lens are orthogonal cemented cylindrical doublets;
the first orthogonal bi-cylindrical lens and the second orthogonal bi-cylindrical lens are disposed on two sides of the Fabry-Perot laser diode respectively; and
the side, opposite to the first AR film, of each of the first orthogonal bi-cylindrical lens and the second orthogonal bi-cylindrical lens is plated with the second AR film.

3. The single-mode external-cavity diode laser based on an s-AFPF according to claim 2, wherein
the wire grid polarizer is a wire grid polarizing film with a diameter of 20 mm, used to generate TE polarized light or TM polarized light, wherein the wire grid polarizing film represents closely arranged thin metal wires/wire array on the top of a transparent substrate;
when the TE polarized light is generated, an intersection of the plane of the wire grid polarizing film and the horizontal plane should be perpendicular to an optical path, the plane of the wire grid polarizing film is not perpendicular to the optical path, and grid wires of the wire grid polarizing film are parallel to the horizontal plane; and
when the TM polarized light is generated, the plane of the wire grid polarizing film is perpendicular to the horizontal plane and not perpendicular to the optical path, and meanwhile, the grid wires are perpendicular to the horizontal plane.

4. The single-mode external-cavity diode laser based on an s-AFPF according to claim 3, wherein
the s-AFPF is a circular single-cavity all-dielectric film Fabry-Perot filter with a diameter of 20 mm.

5. The single-mode external-cavity diode laser based on an s-AFPF according to claim 4, wherein
a high refractive index dielectric of the s-AFPF is Ta₂O₅ film with a physical thickness of 191.247 nm.

6. The single-mode external-cavity diode laser based on an s-AFPF according to claim 5, wherein
a low refractive index dielectric of the s-AFPF is SiO₂ film with a physical thickness of 272.073 nm.

7. The single-mode external-cavity diode laser based on an s-AFPF according to claim 6, wherein
a substrate dielectric of the s-AFPF is BK7(K9) glass with a physical thickness of 2 mm.

8. The single-mode external-cavity diode laser based on an s-AFPF according to claim 7, wherein
an included angle θ is provided between the connecting rod and the s-AFPF, and when the s-AFPF rotates anticlockwise, the included angle θ remains unchanged, wherein based on the included angle R, a rotation angle of the s-AFPF is acquired by acquiring a displacement x of the actuator from an initial position thereof and a distance N between the center of the rotating shaft and the center of the steel ball, which is used for a maximum transmission wavelength of the s-AFPF, and then a pass band center wavelength of the s-AFPF is controlled to occlude with a given external cavity longitudinal mode wavelength, to realize the mode hop-free tuning performance.

9. The single-mode external-cavity diode laser based on an s-AFPF according to claim 8, wherein
a curved groove is further disposed at a sliding joint between the actuator and the steel ball, used to accommodate the steel ball, and prevent the steel ball from generating a ping-pong ball effect.

10. The single-mode external-cavity diode laser based on an s-AFPF according to claim 9, wherein
the laser is applied to a light source of a TDLAS-WMS system for high-precision gas sensing.
